(19) United States
(12) Patent Application Publication
(10) Pub. No.: US 2025/0105130 A1
(43) Pub. Date: Mar. 27, 2025

(54) Electronic Device and Manufacturing Method Thereof

(71) Applicant: Innolux Corporation, Miaoli County (TW)

(72) Inventors: Ker-Yih KAO, Miaoli County (TW); Po-Yun HSU, Miaoli County (TW)

(73) Assignee: Innolux Corporation, Miaoli County (TW)

(21) Appl. No.: 18/808,091

(22) Filed: Aug. 19, 2024

Related U.S. Application Data
(60) Provisional application No. 63/539,605, filed on Sep. 21, 2023.

(30) Foreign Application Priority Data
Jun. 13, 2024 (CN) 202410762631.0

(51) Int. Cl. H01L 23/498; H01L 21/48; H01L 23/00; H01L 23/15; H01L 25/18

(52) U.S. Cl. CPC H01L 23/49838; H01L 21/4857; H01L 21/486; H01L 23/15; H01L 23/49816; H01L 23/49822; H01L 24/16; H01L 25/18; H01L 2224/16227; H01L 2924/35121; H01L 2924/381

(57) ABSTRACT

An electronic device includes a substrate having opposite first and second surfaces and a through hole having an inner wall connected to the first and second surfaces, a buffer layer covering the first and second surfaces and the inner wall, a conductor disposed in the through hole, a first circuit structure disposed on the first surface, an electronic element disposed on the first circuit structure, and first connectors disposed on the second surface and electrically connected to the electronic element through the conductor and the first circuit structure. The through hole has a width W and a depth D, and W/D is greater than or equal to 0.01 and less than or equal to 0.5. A thickness T of the buffer layer is greater than or equal to 0.01 μm and less than or equal to 10 μm. A manufacturing method of an electronic device is also provided.

### CROSS-REFERENCE TO RELATED APPLICATION

This application claims the priority benefit of U.S. provisional application Ser. No. 63/539,605, filed on Sep. 21, 2023 and China application serial no. 202410762631.0, filed on Jun. 13, 2024. The entirety of each of the above-mentioned patent applications is hereby incorporated by reference herein and made a part of this specification.

### BACKGROUND

### Technical Field

The disclosure relates to an electronic device and a manufacturing method thereof.

### Description of Related Art

The development of electronic devices has gradually matured, but problems that need to be addressed can still be found. For instance, in an electronic device, the structural strength of the substrate may be lowered due to formation of the through holes for accommodating the conductors. Further, the manufacturing process of an electronic device is often accompanied by thermal processes, and the mismatch in the coefficients of thermal expansion between the conductor and the substrate can easily lead to cracks in the substrate or interface delamination during the heating and cooling process.

### SUMMARY

The disclosure provides an electronic device and a manufacturing method thereof capable of facilitating improvement of structural strength of a substrate and reduction in generation of cracks in the substrate or interface delamination.

An embodiment of the disclosure provides an electronic device including a substrate, a buffer layer, a conductor, a first circuit structure, an electronic element, and a plurality of first connectors. The substrate has a first surface, a second surface opposite to the first surface, and a through hole. An inner wall of the through hole is connected to the first surface and the second surface. The buffer layer covers the first surface, the second surface, and the inner wall. The conductor is disposed in the through hole. The first circuit structure is disposed on the first surface. The electronic element is disposed on the first circuit structure. The first connectors are disposed on the second surface and are electrically connected to the electronic element through the conductor and the first circuit structure. The through hole has a width W and a depth D, and W/D is greater than or equal to 0.01 and less than or equal to 0.5. Further, a thickness T of the buffer layer is greater than or equal to 0.01 μm and less than or equal to 10 μm.

Another embodiment of the disclosure further provides a manufacturing method of an electronic device, and the manufacturing method further includes the following steps. A through hole is formed in a substrate. An inner wall of the through hole is connected to a first surface of the substrate and a second surface of the substrate, and the second surface is opposite to the first surface. The first surface, the second surface, and the inner wall are covered with a buffer layer. A conductor is formed in the through hole. A first circuit structure is formed on the first surface. An electronic element is arranged on the first circuit structure. A plurality of first connectors are formed on the second surface. The plurality of first connectors are electrically connected to the electronic element through the conductor and the first circuit structure. The through hole has a width W and a depth D, and W/D is greater than or equal to 0.01 and less than or equal to 0.5. Further, a thickness T of the buffer layer is greater than or equal to 0.01 μm and less than or equal to 10 μm.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1F are partial cross-sectional schematic views of a manufacturing process of an electronic device according to some embodiments of the disclosure.

FIG. 2 is an enlarged schematic view of a region R1 in FIG. 1C.

FIG. 3 is a partial cross-sectional schematic view of an electronic device according to some embodiments of the disclosure.

FIG. 4 is a schematic enlarged view of a region R2 in FIG. 3.

FIG. 5 and FIG. 6 are partial cross-sectional schematic views of two electronic devices according to other embodiments of the disclosure.

### DESCRIPTION OF THE EMBODIMENTS

Descriptions of the disclosure are given with reference to the exemplary embodiments illustrated by the accompanying drawings. Wherever possible, the same reference numerals are used in the drawings and the description to refer to the same or like parts.

Certain terminologies will be used to refer to specific elements throughout the specification and the appended claims of the disclosure. People skilled in the art should understand that manufacturers of electronic devices may refer to same elements under different names. The disclosure does not intend to distinguish elements with the same functions but different names. In the following specification and claims, the terminologies “containing”, “comprising”, etc. are open-ended terminologies, so they should be interpreted to mean “including but not limited to . . . “.

In the following embodiments, wording used to indicate directions, such as “up”, “down”, “front”, “back”, “left”, and “right” merely refers to directions in the accompanying figures. Accordingly, the directional terminologies provided herein serve to describe rather than limiting the disclosure. In the accompanying drawings, each figure illustrates methods applied in particular embodiments and general features of structures and/or materials in the embodiments. However, these figures should not be construed or defined as the scope covered by the particular embodiments. For instance, relative dimensions, thicknesses, and positions of various layers, regions, and/or structures may be reduced or enlarged for clarity.

It should be understood that relative terms, for example, “lower”, “bottom”, “higher”, or “top”, may be used in various embodiments to describe the relative relationship of one element of the drawings to another element. It can be understood that if the device in the figures is turned over so that it is upside down, then the elements described as being on the “lower” side will become elements on the “upper” side. Therefore, when it is described that a specific structure is disposed on other structures, it is only for the convenience of description and does not limit the process steps or sequence. The embodiments of the disclosure can be understood together with the accompanying drawings, and the accompanying drawings of the disclosure are also considered as part of the disclosure.

In the disclosure, if one structure (or layer, element, substrate) is described as being located on/above another structure (or layer, element, substrate), it can mean that the two structures are adjacent and are directly connected, or the two structures are adjacent to each other instead of being directly connected. Indirect connection means that at least one intermediary structure (or intermediary layer, intermediary element intermediary substrate, intermediary interval) is provided between two structures, the lower side surface of one structure is adjacent to or is directly connected to the upper side surface of the intermediate structure, and the upper side surface of the other structure is adjacent to or is directly connected to the lower side surface of the intermediate structure. The intermediary structure may be formed by a single-layer or multi-layer physical structure or a non-physical structure, which is not particularly limited. In the disclosure, when a specific structure is arranged to be “on” another structure, it may mean that the specific structure is “directly” on another structure, or it may mean that the specific structure is “indirectly” on another structure, that is, at least one structure is provided between the specific structure and the another structure.

The terms “about”, “substantially”, or “approximately” are generally interpreted as being within 10% of a given value or range, or within 5%, 3%, 2%, 1%, or 0.5% of a given value or range. In addition, the wordings “the range is from the first numerical value to the second numerical value” and “the range falls between the first numerical value and the second numerical value” mean that the range includes the first numerical value, the second numerical value, and other numerical values therebetween.

Terms such as “first” and “second” used in the specification and the claims are used to modify elements, and the terminologies do not imply and represent that the element(s) have any previous ordinal numbers, nor do they represent the order of a specific element and another element or the order of a manufacturing method. The use of the ordinal numbers is only used to clearly distinguish between an element with a specific name and another element with the same name. The claims and the specification may not use the same terminologies. Accordingly, in the specification, a first member may be a second member in the claims.

An electrical connection or coupling relationship described in this disclosure may refer to a direct connection or an indirect connection. In the case of the direct connection, end points of the elements on two circuits are directly connected or connected to each other by a conductor segment, and in the case of the indirect connection, there are switches, diodes, capacitors, inductors, resistors, other appropriate elements, or a combination of the above elements between the end points of the elements on the two circuits, which should not be construed as a limitation in the disclosure.

In the disclosure, the thickness, length, and width may be measured by an optical microscope (OM), and the thickness may be measured from a cross-sectional image in an electron microscope, but the disclosure is not limited thereto. The surface roughness may be measured by using a scanning electron microscope (SEM), a transmission electron microscope (TEM), etc., to observe the surface undulations at an appropriate magnification, and the undulations may be compared by taking a unit length (e.g., 10 μm). Appropriate magnification means that at least one surface may have at least 10 peaks of roughness (Rz) or average roughness (Ra) observed under the magnification.

In addition, certain errors between any two values or directions for comparison may be acceptable. In addition, the wordings “the given range is from the first numerical value to the second numerical value”, “the given range falls within the range of the first numerical value to the second numerical value”, or “the given range falls between the first numerical value and the second numerical value” mean that the given range includes the first numerical value, the second numerical value, and other numerical values therebetween. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meaning as commonly understood by a person of ordinary skill in the art. It is understood that these terms, such as those defined in commonly used dictionaries, should be interpreted as having a meaning consistent with the background or context of the relevant technology and the disclosure, and should not be interpreted in an idealized or excessively formal manner unless specifically defined in the embodiments of the disclosure.

In the disclosure, the electronic device may include but not limited to a power device, a semiconductor packaging device, a display device, a backlight device, an antenna device, a packaging device, a sensing device, or a splicing device. The electronic device may be a bendable or flexible electronic device. The display device may be a non-self-luminous display device or a self-luminous display device. The display device may include but not limited to liquid crystal, a light emitting diode, fluorescence, phosphor, or quantum dots (QDs), other suitable display media, or a combination of the foregoing. The antenna device may include, for example, a reconfigurable intelligent surface (RIS), a frequency selective surface (FSS), a radio frequency filter (RF-filter), a polarizer, a resonator, or an antenna. The antenna may be a liquid crystal type antenna or a varactor diode antenna. The sensing device may be a sensing device that senses capacitance, light, heat energy, or ultrasound, but the disclosure is not limited thereto. In the disclosure, the electronic device may include electronic elements, and the electronic elements may include but not limited to passive elements and active elements, such as known good dies (KGDs), capacitors, resistors, inductors, diodes, transistors, varactor diodes, variable capacitors, filters, sensors, micro-electromechanical systems (MEMS) elements, liquid crystal chips, structures of semiconductor related processes, or structures of semiconductor related processes disposed on a substrate (such as polyimide, glass, silicon substrate, or other suitable substrate materials). The diodes may include light-emitting diodes (LEDs), varactor diodes, or photodiodes. The LEDs may include but not limited to organic LEDs (OLEDs), sub-millimeter LEDs (mini LEDs), micro LEDs, or quantum dot LEDs. The splicing device may be, for example, a display splicing device or an antenna splicing device, but the disclosure is not limited thereto. Note that the electronic device may be any combination of the foregoing, but the disclosure is not limited thereto. The packaging device may be a packaging device applicable to a wafer-level package (WLP) technology or a panel-level package (WLP) technology, such as a chip first process or a chip last/RDL first process. Besides, the appearance of the electronic device may be rectangular, circular, polygonal, or a shape with curved edges, or other suitable shapes. The electronic device may have a peripheral system such as a drive system, a control system, a light source system, etc. to support a display device, an antenna device, a wearable device (such as including augmented reality or virtual reality), a vehicle-mounted device (such as including a car windshield), or a splicing device.

The following embodiments use a packaging device as an example to illustrate some implementations of the electronic device, but the disclosure is not limited thereto. According to the embodiments of the disclosure, a provided manufacturing method of an electronic device may be applied to a wafer-level package (WLP) process or a panel-level package (PLP) process and may adopt a chip first process or a chip last/RDL first process. According to the embodiments of the disclosure, the package structure of the electronic device may include a system on a chip (SoC), a system in package (SiP), an antenna in package (AiP), or a combination thereof, but the disclosure is not limited thereto. According to the embodiments of the disclosure, the electronic device may be applied to a power module, a semiconductor packaging device, a display device, a light-emitting device, a backlight device, an antenna device, a sensing device, or a splicing device, but the disclosure is not limited thereto.

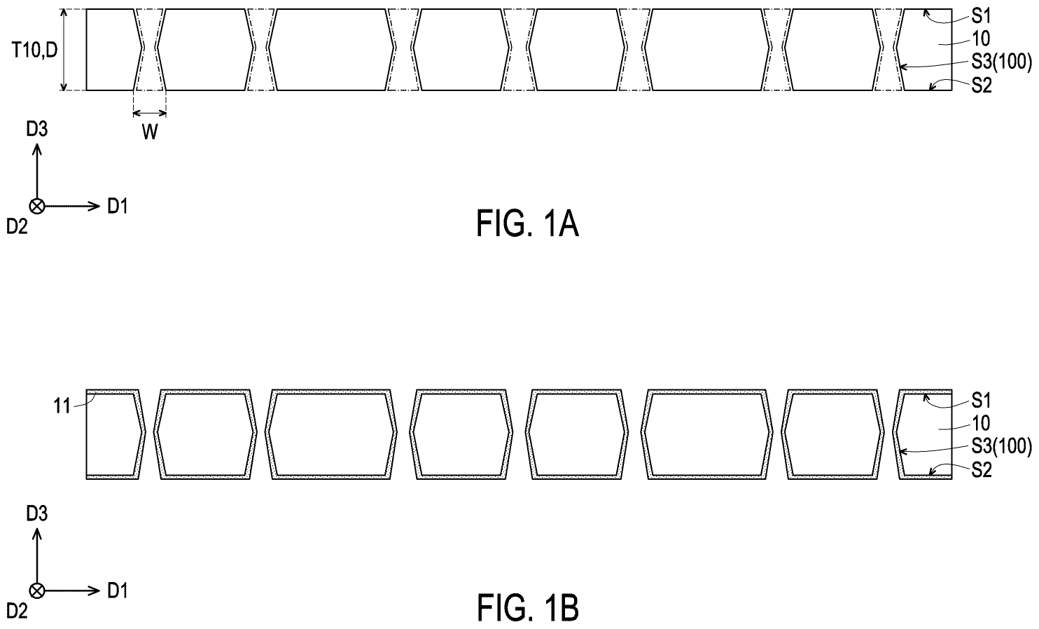

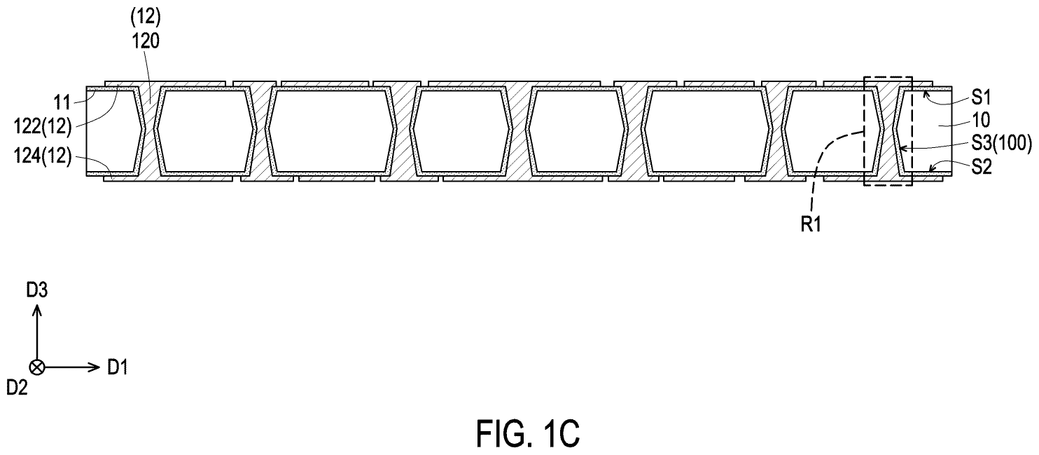

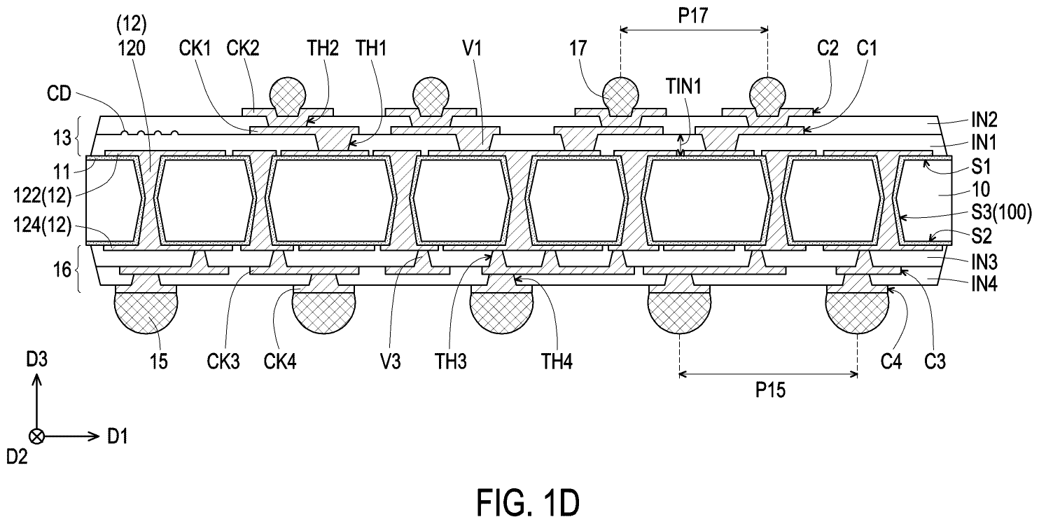

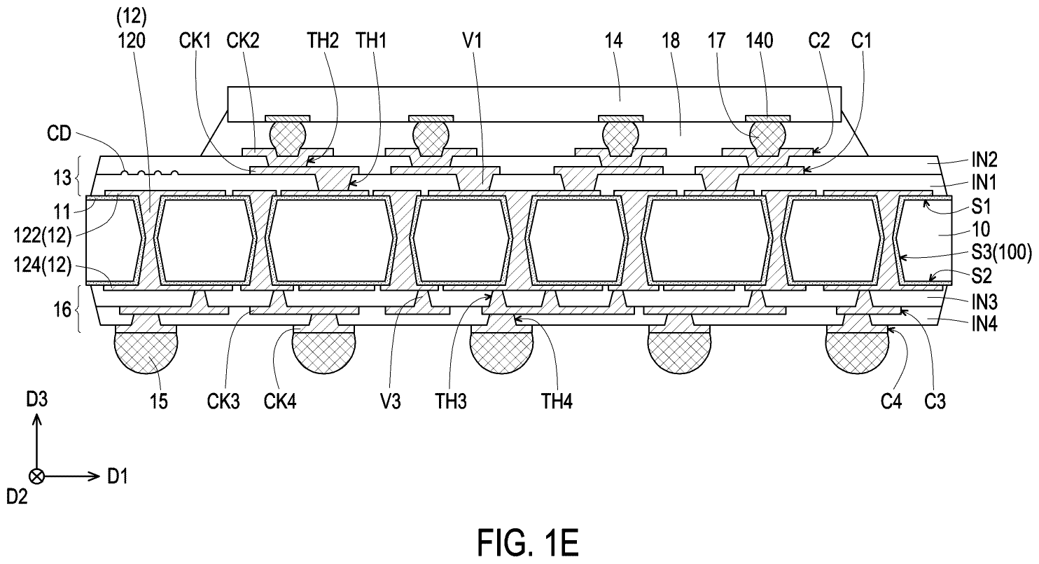

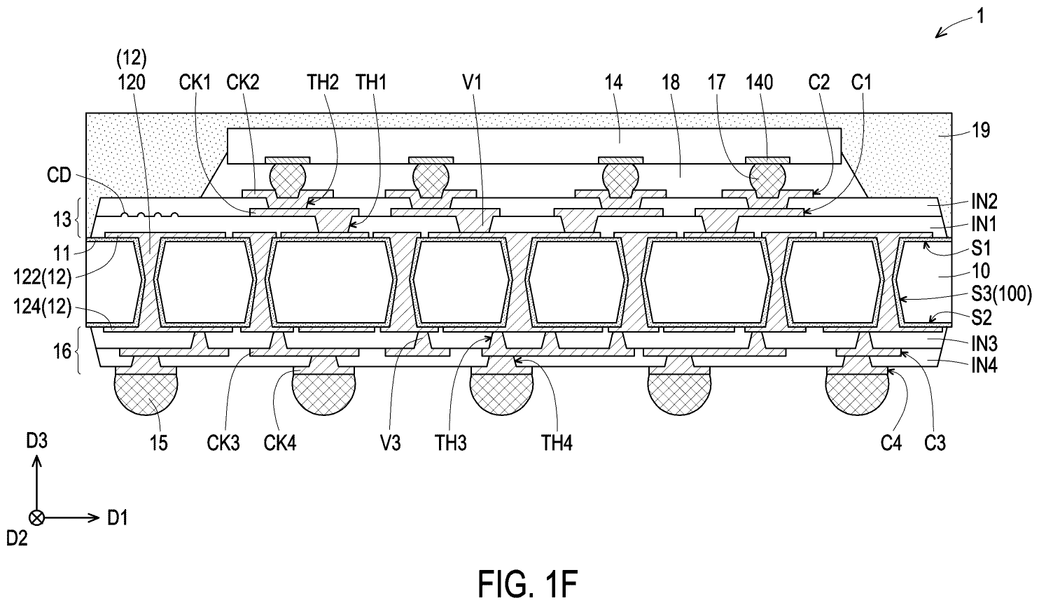

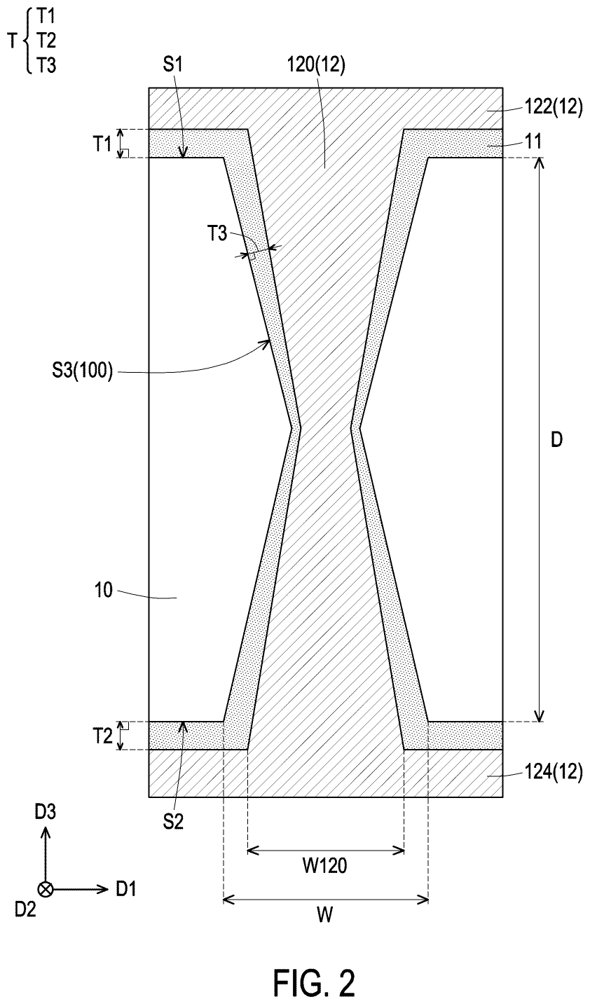

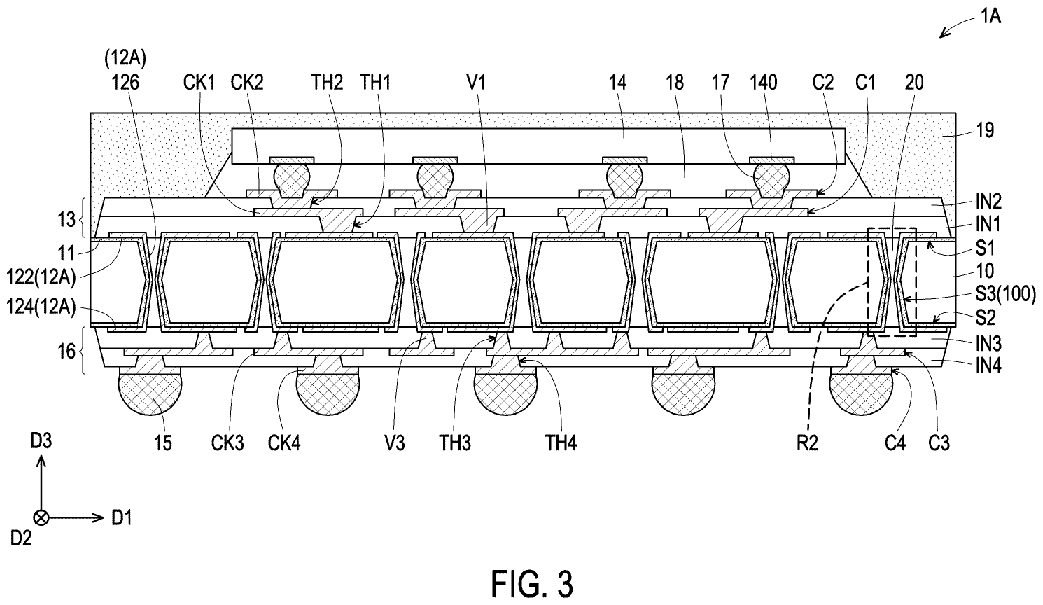

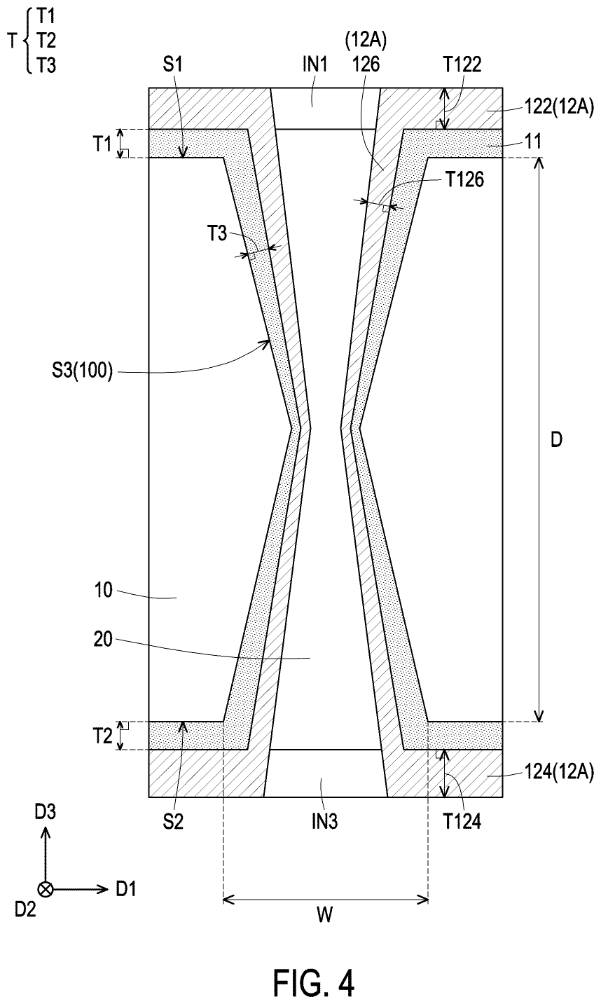

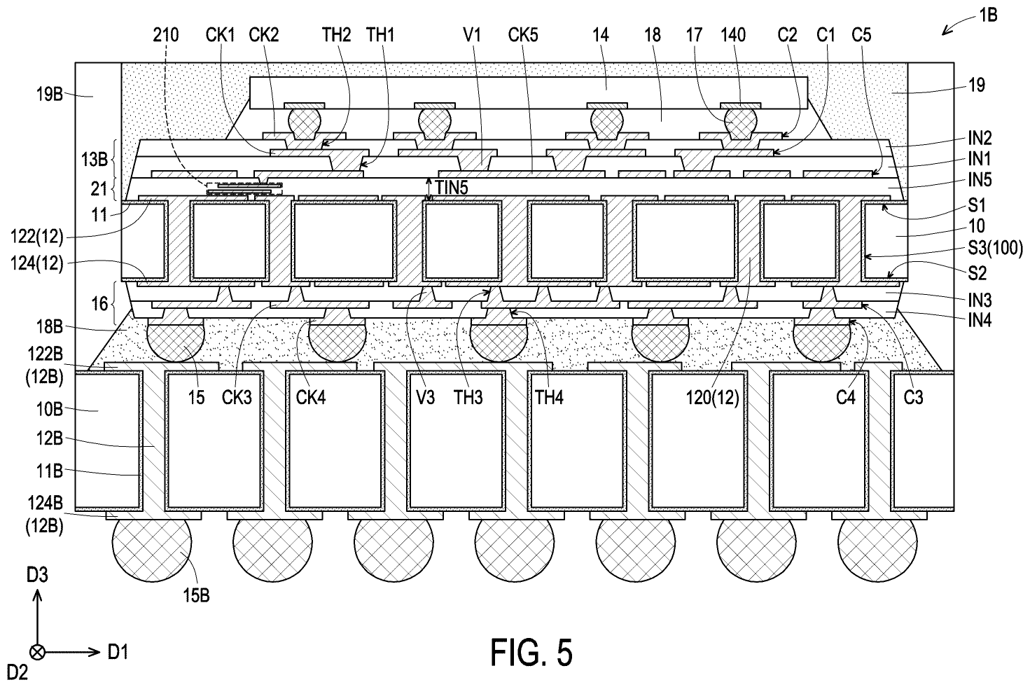

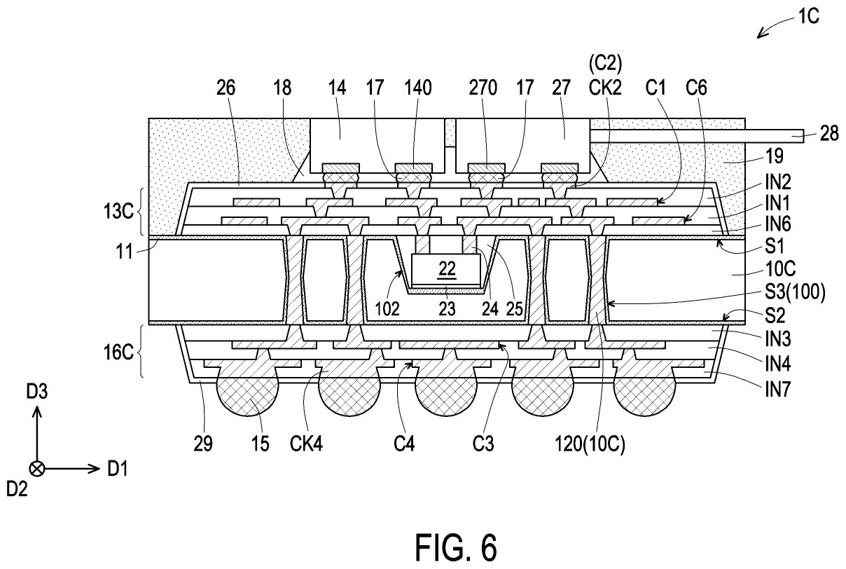

FIG. 1A to FIG. 1F are partial cross-sectional schematic views of a manufacturing process of an electronic device according to some embodiments of the disclosure. FIG. 2 is an enlarged schematic view of a region R1 in FIG. 1C. FIG. 3 is a partial cross-sectional schematic view of an electronic device according to some embodiments of the disclosure. FIG. 4 is a schematic enlarged view of a region R2 in FIG. 3. FIG. 5 and FIG. 6 are partial cross-sectional schematic views of two electronic devices according to other embodiments of the disclosure. It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

According to some embodiments of the disclosure, a manufacturing method of an electronic device may include the following steps. A through hole 100 is formed in a substrate 10. An inner wall S3 of the through hole 100 is connected to a first surface S1 of the substrate 10 and a second surface S2 of the substrate 10, and the second surface S2 is opposite to the first surface S1 (as shown in FIG. 1A). A buffer layer 11 covers at least a portion of the first surface S1, the second surface S2, and the inner wall S3 (as shown in FIG. 1B). A conductor 12 is formed in the through hole 100 (as shown in FIG. 1C). A first circuit structure 13 is formed on the first surface S1 (as shown in FIG. 1D). An electronic element 14 is arranged on the first circuit structure 13 (as shown in FIG. 1E). A plurality of first connectors 15 are formed on the second surface S2. The plurality of first connectors 15 are electrically connected to the electronic element 14 through the conductor 12 and the first circuit structure 13. The through hole 100 has a width W and a depth D, and W/D is greater than or equal to 0.01 and less than or equal to 0.5. Further, a thickness T of the buffer layer 11 is greater than or equal to 0.01 μm and less than or equal to 10 μm (as shown in FIG. 1D, FIG. 1E, FIG. 1F, and/or FIG. 2).

To be specific, with reference to FIG. 1A, the manufacturing method of the electronic device may include forming the through hole 100 in the substrate 10. In some embodiments, a material of the substrate 10 may include glass, ceramic, wafer, or other inorganic materials. The arrangement of the through hole in the substrate of the electronic device can reduce the energy loss caused by a leakage current or improve the heating problem caused by the leakage current under high-speed computing, so that the manufactured electronic device can better meet the standards of energy saving and carbon reduction.

In some embodiments, the method of forming the through hole 100 may include the following. A partial region (such as the region indicated by the dotted line) of the substrate 10 is irradiated with laser, and the partial region (such as the region indicated by the dotted line) of the substrate 10 irradiated with laser is removed with an etchant. To be specific, a region to be removed (e.g., the region where the through hole 100 is to be formed, such as the region indicated by the dotted line) of the substrate 10 may be modified by laser, and then the region of the substrate 10 modified by laser may be removed by an etchant or any suitable solvent to form the through hole 100. The “modification” referred to in the disclosure is to destroy the bonding in a local region of the substrate 10 by laser or other suitable process methods, so as to weaken the structural strength of the local region. According to some embodiments, the etchant may include acid or alkaline, where the acidic etchant includes hydrofluoric acid, and the alkaline etchant includes sodium hydroxide, but the disclosure is not limited thereto.

The through hole 100 is an opening penetrating through the substrate 10, and an inner wall S3 of the through hole 100 is connected to the first surface S1 and the second surface S2 of the substrate 10. In other words, the depth D of the through hole 100 is equal to the thickness T10 of the substrate 10, where a thickness T10 of the substrate 10 is a maximum distance between the first surface S1 of the substrate 10 and the second surface S2 of the substrate 10 in a direction D3. According to some embodiments, the inner wall S3 may have a curved contour.

In FIG. 1A, seven through holes 100 arranged in a direction D1 are schematically illustrated, and a cross-sectional shape of each through hole 100 is an hourglass shape. In other words, in the cross-sectional view, as shown in FIG. 1A, the width W of the through hole 100 decreases from the surface (e.g., the first surface S1 or the second surface S2) of the substrate 10 toward a center of the substrate 10. That is, the through hole 100 has a minimum width, where a distance between the position of the minimum width and the surface of the substrate 10 (e.g., the first surface S1 or the second surface S2) is greater than or equal to 0.4D and less than or equal to 0.6D. However, design parameters such as the number of through holes 100, the arrangement of through holes 100, and/or the cross-sectional shape of through holes 100 may be changed according to actual needs and are not limited to what is shown in FIG. 1A. For instance, the cross-sectional shape of the through holes 100 may be a rectangle or other polygons. In addition, the substrate 10 may include more or fewer through holes 100. Further, the plurality of through holes 100 may be arranged in an array in a direction D1 and a direction D2, where the direction D1 and the direction D2 intersect each other and are perpendicular to the direction D3. In some embodiments, the direction D1 and the direction D2 may be perpendicular to each other, but the disclosure is not limited thereto. Through the above design, the quality of electrical signal transmission of the electronic device may be improved, but the disclosure is not limited thereto.

In some embodiments, considering process costs, time, yield, and/or structural strength of the substrate 10, a ratio of the depth D of each through hole 100 to the width W (e.g., a maximum width of the through hole 100) of the through hole 100 is greater than or equal to 2 and less than or equal to 100, greater than or equal to 5 and less than or equal to 15, greater than or equal to 7 and less than or equal to 12, that is, 2≤D/W≤100.

With reference to FIG. 1B, the manufacturing method of the electronic device may further include covering at least a portion of the first surface S1, at least a portion of the second surface S2, and at least a portion of the inner wall S3 with the buffer layer 11. That is, the buffer layer 11 may directly contact at least a portion of the first surface S1, at least a portion of the second surface S2, and at least a portion of the inner wall S3. The buffer layer 11 may be used to enhance adhesion between the substrate 10 and the conductor 12 (with reference to FIG. 1C) formed subsequently, so that the detachment problem between the substrate 10 and the conductor 12 is further improved. In addition, the buffer layer 11 may utilize strain to release internal stress generated by heat or other processes, so that the structural strength of the substrate 10 is improved, or the generation of cracks in the substrate 10 is reduced. For instance, a material of the buffer layer 11 may include polyimide (PI), parylene, benzocyclobutene (BCB), epoxy, polycarbonate (PC), polyethylene terephthalate (PET), polyethylene terephthalate (PEN), carbide, silicide, sulfide, other suitable materials, or a combination of the foregoing. According to some embodiments, the buffer layer 11 may include a single layer of material or a stack of multiple layers of material, where the multiple layers of material may be the same as or different from each other.

In some embodiments, the method of forming the buffer layer 11 may include forming the material of the buffer layer 11 on the first surface S1, the second surface S2, and the inner wall S3 by chemical vapor deposition, atomic layer deposition (ALD), plating, electroplating, liquid phase deposition, or other suitable processes. For instance, first chemical vapor deposition may be performed from one side (e.g., the side where one of the first surface S1 and the second surface S2 is located) of the substrate 10, and then the substrate 10 is turned over. Next, second chemical vapor deposition is performed from the other side (e.g., the side where the other one of the first surface S1 and the second surface S2 is located) of the substrate 10 to form the buffer layer 11 covering the first surface S1, the second surface S2, and the inner wall S3. Alternatively, chemical vapor deposition may be performed from a single side (e.g., the side where one of the first surface S1 and the second surface S2 is located) of the substrate 10 to form the buffer layer 11 covering the first surface S1, the second surface S2, and the inner wall S3. Alternatively, chemical vapor deposition may be performed from two sides (e.g., the sides where one of the first surface S1 and the second surface S2 is located) of the substrate 10 together to form the buffer layer 11 covering the first surface S1, the second surface S2, and the inner wall S3.

In some other embodiments, the method of forming the buffer layer 11 may include immersing the substrate 10 having the through hole 100 in a solution, wherein the solution includes organic solution or inorganic solution, for example, the organic solution includes polymer, epoxy other suitable materials, but not limited to. In some other embodiments, providing organic solution to cover the substrate 10 having the through hole 100 includes spray, coating, or any suitable method, but not limited to. Before immersing the substrate 10 having the through hole 100 in the polymer solution, the substrate 10 may be selectively subjected to surface treatment to enhance the adhesion of the buffer layer 11 to the substrate 10 or reduce the risk of the buffer layer 11 being detached from the substrate 10. The surface treatment may include a cleaning step, a laser irradiation step, a chemical treatment step, a temperature increase step, other appropriate steps, or a combination of the foregoing.

In some embodiments, considering process costs, time, yield, and/or structural strength of the substrate 10, the thickness T of the buffer layer 11 (with reference to FIG. 2) is greater than or equal to 0.01 μm and less than or equal to 10 μm, that is, 0.01 μm≤T≤10 μm. The thickness T of the buffer layer 11 is measured in a vertical direction (or normal direction) from the arrangement surface (e.g., the first surface S1, the second surface S2, and the inner wall S3). As shown in FIG. 2, the thickness T of the buffer layer 11 may include a thickness T1 of the buffer layer 11 covering the first surface S1, a thickness T2 of the buffer layer 11 covering the second surface S2, and a thickness T3 of the buffer layer 11 covering the inner wall S3. In some embodiments, the thickness T1 of the buffer layer 11 covering the first surface S1 and the thickness T2 of the buffer layer 11 covering the second surface S2 are greater than the thickness T3 of the buffer layer 11 covering the inner wall S3. In addition, the thickness T3 increases, for example, from a portion close to the thickness center of the substrate 10 toward a surface (e.g., the first surface S1 or the second surface S2) of the substrate 10.

In some embodiments, the ratio of the thickness T of the buffer layer 11 to the width W of the through hole 100 is greater than or equal to 0.002 and less than or equal to 0.2, that is, 0.002≤T/W≤0.2, so that the structural strength of the substrate 10 is improved and the damage to the substrate 10 caused by the internal stress generated in the subsequent process is lowered. For instance, when W=5 μm, T is greater than or equal to 0.1 μm and less than or equal to 1 μm, when W=50 μm, T is greater than or equal to 0.1 μm and less than or equal to 5 μm, and when W=100 μm, T is greater than or equal to 2 μm and less than or equal to 10 μm.

With reference to FIG. 1C, the manufacturing method of the electronic device may further include forming the conductor 12 in the through hole 100. The conductor 12 may be used to electrically connect a plurality of conductive structures individually located on the first surface S1 and the second surface S2 of the substrate 10. For instance, a material of the conductor 12 may include metal, alloy, or a combination of the foregoing, and the method of forming the conductor 12 may include but not limited to electroplating, chemical plating, atomic layer deposition (ALD), or a combination of the foregoing. In some embodiments, as shown in FIG. 1C, there may be a plurality of conductors 12, and the plurality of conductors 12 are formed in a plurality of through holes 100. For instance, each through hole 100 may be provided with one corresponding conductor 12, and the conductor 12 may fill a space outside the buffer layer 11 in the through hole 100, but the disclosure is not limited thereto. Taking FIG. 1C as an example, the conductors 12 may include conductive columns 120, and the cross-sectional shape of each of the conductive columns 120 may be an hourglass shape. In other words, in the cross-sectional view, as shown in FIG. 2, a width W120 of the conductive column 120 increases from the thickness center of the substrate 10 toward the surface (e.g., the first surface S1 or the second surface S2) of the substrate 10. In some embodiments, as shown in FIG. 1C, each of the conductors 12 may further include a circuit 122 disposed on the first surface S1 and a circuit 124 disposed on the second surface S2, but the disclosure is not limited thereto. Two opposite ends of each of the conductive columns 120 may be connected to one corresponding circuit 122 and one corresponding circuit 124.

With reference to FIG. 1D, the manufacturing method of the electronic device may further include forming the first circuit structure 13 on the first surface S1. The first circuit structure 13 may also be referred to as a first redistribution structure, which may be electrically connected to other elements (e.g., the electronic element 14 shown in FIG. 1E) through a plurality of connectors (a plurality of second connectors 17). The first circuit structure 13 may include one or more dielectric layers and one or more conductive layers. In FIG. 1D, two dielectric layers and two conductive layers are used as an example for illustration, but the first circuit structure 13 may include more or less dielectric layers and conductive layers as required. Through at least one dielectric layer and at least one conductive layer, circuits may be redistributed and/or a circuit fan-out or fan-in area may be increased, or different electronic elements may be electrically connected to each other through a redistribution structure. For instance, a pitch between two adjacent contact pads at one end of the redistribution structure contacting the electronic element 14 may be smaller than or equal to a pitch between two adjacent contact pads at one end of the redistribution structure away from the electronic element 14. Therefore, the redistribution structure may adjust a circuit fan-out condition or electrically connect a circuit structure/electronic element having a first pitch to a circuit structure/electronic element having a second pitch. Herein, a width of the contact pad at one end of the redistribution structure contacting the electronic element 14 may be smaller than a width of the contact pad at the end of the redistribution structure away from the electronic element 14, but the disclosure is not limited thereto. The method of forming the first circuit structure 13 may include forming at least one dielectric layer and at least one conductive layer using a photolithography process, a surface treatment process, a laser process, a plating process, a deposition process, or other processes. The surface treatment process includes roughening the surface of the dielectric layer or the conductive layer to improve its bonding ability.

Taking FIG. 1D as an example, the first circuit structure 13 includes a dielectric layer IN1, a conductive layer C1, a dielectric layer IN2, and a conductive layer C2 sequentially formed on the first surface S1, but the disclosure is not limited thereto. A material of the dielectric layer IN1 and the dielectric layer IN2 may include but not limited to polyimide (PI), photosensitive polyimide (PSPI), polybenzoxazole (PBO), epoxy resin, polymer, ajinomoto build-up film (ABF), silicon oxide, silicon nitride, or a combination of the foregoing Each of the conductive layer C1 and the conductive layer C2 may be a single conductive layer or a conductive stacked layer. In addition, a material of the conductive layer C1 and the conductive layer C2 may include metal, alloy, or a combination of the foregoing. For instance, when the conductive layer C1 and the conductive layer C2 are conductive stacked layers, the conductive layer may include a stack of a seed layer and a conductive layer. Herein, the seed layer is able to increase the bonding strength between a subsequent film layer and a previous film layer or is able to improve the quality of subsequent film layer formation during the process, such as improving the continuity of the subsequent film layer, but the disclosure is not limited thereto. A material of the conductive layer may include but not limited to copper, titanium, ruthenium, arsenic, tungsten, tantalum, gallium, nickel, gold, palladium, cobalt, alloys, a combination of the foregoing, or other suitable materials.

The dielectric layer IN1 is disposed on the buffer layer 11 and the conductor 12 and includes a plurality of through holes TH1. Each of the through holes TH1 exposes a local region of one corresponding circuit 122. The conductive layer C1 may be a patterned conductive layer and may include a plurality of circuits CK1 and a plurality of conductive vias V1. The plurality of circuits CK1 may be disposed on the dielectric layer IN1. Each of the conductive vias V1 is disposed in one corresponding through hole TH1. Each of the circuits CK1 may be electrically connected to one corresponding circuit 122 through one corresponding conductive via V1. The dielectric layer IN2 is disposed on the dielectric layer IN1 and the conductive layer C1 and includes a plurality of through holes TH2. Each of the through holes TH2 exposes a local region of one corresponding circuit CK1. The conductive layer C2 may be a patterned conductive layer and may include a plurality of contact pads CK2. Each of the contact pads CK2 is disposed in one corresponding through hole TH2 and may selectively extend onto the dielectric layer IN2. According to some embodiments, a portion of the dielectric layer IN1 may be patterned to form a plurality of dummy pads CD. Herein, in the direction D1, a spacing between two adjacent dummy pads CD is less than or equal to half of a maximum thickness TIN1 of the dielectric layer IN1 in the direction D3. Through arrangement of the dummy pads CD, the alignment accuracy in the process may be improved, or the bonding ability between different film layers may be improved, but the disclosure is not limited thereto.

In some embodiments, a ratio of toughness of the buffer layer 11 to toughness of a dielectric layer (e.g., the dielectric layer IN1) of the first circuit structure 13 is greater than or equal to 0.1 and less than or equal to 10. For instance, the buffer layer 11 may effectively utilize strain to release the internal stress generated by heat or other processes, so that the structural strength of the substrate 10 is improved, or the generation of cracks in the substrate 10 is reduced. In some embodiments, the toughness of the buffer layer 11 is greater than or equal to 0.1 kJ/m2 and less than or equal to 100 KJ/m2. In the specification, the toughness of the film layer may be obtained by integrating the area under the stress-strain curve, which may be obtained by performing a tensile test on the film layer using a universal testing machine.

In some embodiments, as shown in FIG. 1D and FIG. 2, a thickness (e.g., maximum thickness TIN1 of the dielectric layer IN1 in the direction D3) of the dielectric layer (e.g., dielectric layer IN1) of the first circuit structure 13 may be greater than the thickness T of the buffer layer 11. In some embodiments, the thickness (e.g., maximum thickness TIN1) of the dielectric layer (e.g., dielectric layer IN1) of the first circuit structure 13 is greater than or equal to 5 μm and less than or equal to 25 μm, that is 5 μm≤TIN1≤25 μm, but the disclosure is not limited thereto.

In some embodiments, as shown in FIG. 1D, the manufacturing method of the electronic device may further include forming the plurality of second connectors 17 on the first circuit structure 13. The plurality of second connectors 17 may be electrically connected to the plurality of contact pads CK2.

In some embodiments, as shown in FIG. 1D, the manufacturing method of the electronic device may further include forming a second circuit structure 16 on the second surface S2. The second circuit structure 16 may also be referred to as a second redistribution structure, which may be electrically connected to other elements (not shown, such as a circuit board) through a plurality of connectors (such as a plurality of first connectors 15). The second circuit structure 16 may include one or more dielectric layers and one or more conductive layers. In FIG. 1D, two dielectric layers and two conductive layers are used as an example for illustration, but the second circuit structure 16 may include more or less dielectric layers and conductive layers as required. Through at least one dielectric layer and at least one conductive layer, circuits may be redistributed and/or a circuit fan-out or fan-in area may be increased, or different electronic elements may be electrically connected to each other through the second circuit structure 16. For instance, a pitch between two adjacent contact pads at one end of the redistribution structure contacting a circuit board may be greater than or equal to a pitch between two adjacent contact pads at one end of the redistribution structure away from the circuit board. Therefore, the redistribution structure may adjust the circuit fan-out condition or electrically connect the circuit structure/electronic element having the first pitch to the circuit structure/electronic element having the second pitch, but the disclosure is not limited thereto. The method for forming the second circuit structure 16 may refer to the aforementioned method for forming the first circuit structure 13, so description thereof is not repeated herein.

Taking FIG. 1D as an example, the second circuit structure 16 includes a dielectric layer IN3, a conductive layer C3, a dielectric layer IN4, and a conductive layer C4 sequentially formed on the second surface S2, but the disclosure is not limited thereto. Description of materials of the dielectric layer IN3 and the dielectric layer IN4 may refer to the description of the materials of the dielectric layer IN1 and the dielectric layer IN2, so description thereof is not repeated herein. Each of the conductive layer C3 and the conductive layer C4 may be a single conductive layer or a conductive stacked layer. In addition, materials of the conductive layer C3 and the conductive layer C4 may refer to the materials of the conductive layer C1 and the conductive layer C2, so description thereof is not repeated herein.

The dielectric layer IN3 is disposed on the buffer layer 11 and the conductor 12 and includes a plurality of through holes TH3. Each of the through holes TH3 exposes a local region of one corresponding circuit 124. The conductive layer C3 may be a patterned conductive layer and may include a plurality of circuits CK3 and a plurality of conductive vias V3. The plurality of circuits CK3 may be disposed on the dielectric layer IN3. Each of the conductive vias V3 is disposed in one corresponding through hole TH3. Each of the circuits CK3 may be electrically connected to one corresponding circuit 124 through one corresponding conductive via V3. The dielectric layer IN4 is disposed on the dielectric layer IN3 and the conductive layer C3 and includes a plurality of through holes TH4. Each of the through holes TH4 exposes a local region of one corresponding circuit CK3. The conductive layer C4 may be a patterned conductive layer and may include a plurality of contact pads CK4. Each of the contact pads CK4 is disposed in one corresponding through hole TH4 and may selectively extend onto the dielectric layer IN4.

The manufacturing method of the electronic device may further include forming the plurality of first connectors 15 on the second surface S2. Taking FIG. 1D as an example, the plurality of first connectors 15 may be electrically connected to the plurality of contact pads CK4, and a pitch P15 of the plurality of first connectors 15 is, for example, greater than a pitch P17 of the plurality of second connectors 17. To be specific, the pitch P15 of the first connectors 15 corresponds to the pitch of two adjacent contact pads CK4 of the second circuit structure 16 contacting one end of the circuit board (not shown), and the pitch P17 of the second connectors 17 corresponds to the pitch of two adjacent contact pads CK2 at one end of the first circuit structure 13 contacting the electronic element 14. By adjusting the circuit fan-out condition through the first circuit structure 13, the conductor 12, and the second circuit structure 16, circuit structures/electronic elements (e.g., the electronic element 14 and the circuit board not shown) with different pitches may be electrically connected.

With reference to FIG. 1E, the manufacturing method of the electronic device may further include arranging the electronic element 14 on the first circuit structure 13. Herein, the plurality of first connectors 15 may be electrically connected to the electronic element 14 through the second circuit structure 16, the conductor 12, the first circuit structure, 13 and the plurality of second connectors 17. The electronic element 14 may be a digital chip, an analog chip, a mixed signal chip, a logic chip, a sensor chip, a structure of a semiconductor-related process, a structure of a semiconductor-related process disposed on a substrate (e.g., polyimide, glass, silicon substrate, or other suitable substrate materials), other types of integrated circuit chips, or a combination of the foregoing.

In some embodiments, the electronic element 14 may be transferred to the first circuit structure 13 by a pick and place (PnP) process, and a plurality of pads 140 of the electronic element 14 may be bonded to the plurality of second connectors 17. In other embodiments, although not shown in FIG. 1E, a plurality of electronic elements may be transferred onto the first circuit structure 13 and bonded to the first circuit structure 13. The plurality of electronic elements may include a plurality of electronic elements having different design parameters such as usage, size, type, shape, number of pads, and/or pad pitch, but the disclosure is not limited thereto.

In some embodiments, the manufacturing method of the electronic device may further include forming an underfill 18 between the first circuit structure 13 and the electronic element 14. Herein, the underfill 18 surrounds the second connectors 17 to protect the second connectors 17 or enhance the adhesion between the first circuit structure 13 and the electronic element 14.

With reference to FIG. 1F, the manufacturing method of the electronic device may further include forming a packaging layer 19 on the first circuit structure 13, the underfill 18, and the electronic element 14. A material of the packaging layer 19 includes but not limited to, for example, a molding compound, resin (e.g., epoxy resin), polymer, or a combination thereof. In some embodiments, although not shown, the packaging layer 19 may be thinned by a planarization process to expose a surface of the electronic element 14 away from the substrate 10. This design can improve the heat dissipation capacity of electronic device, but the disclosure is not limited thereto. The planarization process may include a mechanical grinding process, a chemical mechanical polishing (CMP) process, or a combination of the foregoing.

It should be understood that FIG. 1A to FIG. 1F are only schematic views showing one manufacturing process of the electronic device 1. However, the manufacturing process of the electronic device 1 is not limited thereto. For instance, the manufacturing sequence, the number of elements/film layers, the arrangement of elements, or the electrical connection method may be changed according to actual needs. For instance, the plurality of first connectors 15 may be formed after the packaging layer 19 is formed, but the disclosure is not limited thereto.

After completing the steps shown in FIG. 1A to FIG. 1F, the manufacturing of the electronic device 1 is preliminarily completed. According to some embodiments of the disclosure, the electronic device 1 may include the substrate 10, the buffer layer 11, the conductor 12, the first circuit structure 13, the electronic element 14, and the plurality of first connectors 15. The substrate 10 has the first surface S1, the second surface S2 opposite to the first surface S1, and the through hole 100. The inner wall S3 of the through hole 100 is connected to the first surface S1 and the second surface S2. The buffer layer 11 covers the first surface S1, the second surface S2, and the inner wall S3. The conductor 12 is disposed in the through hole 100. The first circuit structure 13 is disposed on the first surface s1. The electronic element 14 is disposed on the first circuit structure 13. The first connectors 15 are disposed on the second surface S2 and are electrically connected to the electronic element 14 through the conductor 12 and the first circuit structure 13. The through hole 100 has the width W and the depth D, and W/D is greater than or equal to 0.01 and less than or equal to 0.5. The thickness T of the buffer layer 11 is greater than or equal to 0.01 μm and less than or equal to 10 μm. According to some embodiments, the average surface roughness of the inner wall S3 may be between 0.01 μm and 1.2 μm. Through the above design, the bonding force between the subsequent film layer and the inner wall S3 may be improved.

In some embodiments, as described above, T/W may be greater than or equal to 0.002 and less than or equal to 0.2. In some embodiments, as described above, the electronic device 1 may further optionally include the second circuit structure 16, which is disposed on the second surface S2 and is located between the substrate 10 and the plurality of first connectors 15. In some embodiments, the electronic element 14 may be electrically connected to the second circuit structure 16 through the conductor 12 and the first circuit structure 13. In some embodiments, as described above, the electronic device 1 may further optionally include the plurality of second connectors 17. Herein, the electronic element 14 is electrically connected to the first circuit structure 13 through the plurality of second connectors 17. Further, the pitch P15 (with reference to FIG. 1D) of the plurality of first connectors 15 is, for example, greater than the pitch P17 (with reference to FIG. 1D) of the plurality of second connectors 17. In some embodiments, as described above, the ratio of the toughness of the buffer layer 11 to the toughness of the dielectric layer IN1 of the first circuit structure 13 is greater than or equal to 0.1 and less than or equal to 10. In some embodiments, the toughness of the buffer layer 11 may be greater than or equal to 0.1 kJ/m2 and less than or equal to 100 KJ/m2. In some embodiments, as described above, the thickness (e.g., the maximum thickness TIN1, with reference to FIG. 1D) of the dielectric layer IN1 of the first circuit structure 13 may be greater than the thickness T of the buffer layer 11 (with reference to FIG. 2). In some embodiments, the thickness (e.g., the maximum thickness TIN1, with reference to FIG. 1D) of the dielectric layer IN1 of the first circuit structure 13 may be greater than or equal to 5 μm and less than or equal to 25 μm. In some embodiments, the conductor 12 may fill the space outside the buffer layer 11 in the through hole 100.

With reference to FIG. 3 and FIG. 4, the main differences between an electronic device 1A and the electronic device 1 shown in FIG. 1F and FIG. 2 are described as follows. In the electronic device 1A, according to some embodiments, a conductor 12A is a conformal layer extending from the inner wall S3 to the first surface S1 and the second surface S2. Alternatively, according to some embodiments, a portion of the conductor 12A may be formed on one of the first surface S1 and the second surface S2 first, and then a portion of the conductor 12A may be formed on the other surface, and the two surfaces may be connected to form the final conductor 12A. Herein, a thickness (e.g., thickness T122 or thickness T124) of the conductor 12A on the first surface S1 or the second surface S2 is greater than the thickness (e.g., thickness T1 or thickness T2) of the buffer layer 11 covering the first surface S1 or the second surface S2. Further, the thickness (e.g., thickness T1 or thickness T2) of the buffer layer 11 covering the first surface S1 or the second surface S2 is greater than the thickness of the buffer layer 11 covering the inner wall S2. To be specific, the conductor 12A includes, for example, the circuit 122, the circuit 124, and a connecting line 126. Herein, the circuits 122, the circuits 124, and the connecting line 126 are disposed on the first surface S1, the second surface S2, and the inner wall S3, respectively, and the connecting line 126 is electrically connected to one corresponding circuit 122 and one corresponding circuit 124. A thickness of the conductor 12A on the first surface S1 is equal to the thickness T122 of the circuit 122, and a thickness of the conductor 12A on the second surface S2 is equal to the thickness T124 of the circuit 124. Based on considerations of electrical transmission capability or reliability, the thickness T122 and/or the thickness T124 may be greater than the thickness T1 and/or the thickness T2. In addition, depending on the manufacturing method used, the thickness T1 and/or the thickness T2 may be greater than the thickness T3. Similarly, the thickness T122 and/or the thickness T124 may be greater than a thickness T126 of the connecting line 126. In some embodiments, as shown in FIG. 4, the thickness T126 of the connecting line 126 may increase from a portion close to the thickness center of the substrate 10 toward the surface (e.g., the first surface S1 or the second surface S2) of the substrate 10.

In some embodiments, the electronic device 1A may further include a dielectric layer 20, and the dielectric layer 20 may fill the space outside the buffer layer 11 in the through hole 100 and the conductor 12A. That is, a gap in the through hole 100 not occupied by the buffer layer 11 and the conductor 12A may be filled with the dielectric layer 20. In some embodiments, a dissipation factor (Df) of the dielectric layer 20 may be less than 0.01 at an operating frequency of 10 MHz, so that the electrical insulation capability of the substrate 10 is improved, energy loss caused by the leakage current is reduced, or the heating problem caused by the leakage current under high-speed computing is addressed.

With reference to FIG. 5, the main differences between an electronic device 1B and the electronic device 1 shown in FIG. 1F are described as follows. In the electronic device 1B, the cross-sectional shape of the conductive column 120 is a rectangle. In addition, the electronic device 1B further includes an element integration layer 21 disposed between the substrate 10 and a first circuit structure 13B and including another electronic element (e.g., electronic element 210) electrically connected to the electronic element 14 through the first circuit structure 13B. According to different needs, the electronic element 210 may include an active element, a passive element, or a combination of the foregoing. For instance, the electronic element 210 may include but not limited to an integrated passive device (IPD), a transistor, or a combination of the foregoing. In some embodiments, the element integration layer 21 may further include a dielectric layer IN5, and the electronic element 210 is located in the dielectric layer IN5. The dielectric layer IN5 may be a single layer or a composite layer, where when the dielectric layer IN5 is a composite layer (e.g., n layers), a total thickness TIN5 of the dielectric layer IN5 divided by n is, for example, less than or equal to the maximum thickness TIN1 of the dielectric layer IN1 in the direction D3. A material and other designs of the dielectric layer IN5 may refer to the description of the dielectric layer IN1 in the foregoing paragraphs, but the material of the dielectric layer IN5 may be different from the material of the dielectric layer IN1, so description thereof is not repeated herein. In some embodiments, as shown in FIG. 5, the first circuit structure 13B may further include a conductive layer C5 in addition to the dielectric layer IN1, the conductive layer C1, the dielectric layer IN2, and the conductive layer C2. The conductive layer C5 is disposed on the dielectric layer IN5 and may be a patterned conductive layer. For instance, the conductive layer C5 may include a plurality of circuits CK5. At least one circuit CK5 may be electrically connected to the electronic element 210. The dielectric layer IN1 is disposed on the dielectric layer IN5 and the conductive layer C5 and each through hole TH1 exposes a local region of one corresponding circuit CK5. Each of the circuits CK1 may be electrically connected to one corresponding circuit CK5 through one corresponding conductive via V1.

In some embodiments, as shown in FIG. 5, the electronic device 1B may further include but not limited to a conductive through-hole substrate U, an underfill 18B, a packaging layer 19B, and a plurality of third connectors 15B. The conductive through-hole substrate U may be electrically connected to the second circuit structure 16 through the plurality of first connectors 15. The underfill 18B surrounds the first connectors 15 to protect the first connectors 15 or enhance the adhesion between the second circuit structure 16 and the conductive through-hole substrate U. The packaging layer 19B is disposed on the conductive through-hole substrate U and the underfill 18B and may surround the packaging layer 19, the substrate 10, and the second circuit structure 16. A material of the packaging layer 19B may refer to the material of the packaging layer 19, so description thereof is not repeated herein. The conductive through-hole substrate U may include a substrate 10B and a conductor 12B. Herein, materials, manufacturing methods, and/or relative arrangement relationships of the substrate 10B and the conductor 12B may refer to the relevant description of the substrate 10 and the conductor 12, so description thereof is not repeated herein. In some embodiments, the conductor 12B may include a plurality of circuits 122B and a plurality of circuits 124B, where the plurality of circuits 122B and the plurality of circuits 124B are disposed on opposite surfaces of the substrate 10B. The plurality of circuits 122B may be electrically connected to the plurality of first connectors 15, and the plurality of circuits 124B may be electrically connected to the plurality of third connectors 15B.

With reference to FIG. 6, the main differences between an electronic device 1C and the electronic device 1 shown in FIG. 1F are described as follows. In the electronic device 1C, a conductor 12C includes the conductive column 120 and does not include the aforementioned circuit 122 and circuit 124. A substrate 10C further includes a blind hole 102, and the electronic device 1C further includes another electronic element (e.g., electronic element 22) disposed in the blind hole 102 and electrically connected to the electronic element 14 through the first circuit structure 13C. The electronic element 22 may be a connector or other types of electronic elements, which is not limited herein. In some embodiments, the electronic device 1C may further include an adhesive layer 23, a conductor 24, and a filling layer 25. The electronic element 22 may be fixed in the blind hole 102 via the adhesive layer 23. The adhesive layer 23 includes but not limited to a die attach film (DAF), polyimide, photosensitive polyimide, optical clear adhesive (OCA), or optical clear resin (OCR), for example. The electronic element 22 may be electrically connected to the first circuit structure 13C via the conductor 24. The conductor 24 includes, for example, a conductive bump or other conductive media. The filling layer 25 may fill a space in the blind hole 102 that is not occupied by the electronic element 22, the adhesive layer 23, and the conductor 24, and the filling layer 25 may expose one end of the conductor 24 to be connected to the first circuit structure 13C. A material of the filling layer 25 may include an underfill or other insulating filling materials. In some embodiments, a top surface of the conductor 24 and a top surface of the filling layer 25 may be flush or have the same height, but the disclosure is not limited thereto.

The first circuit structure 13C may include a dielectric layer IN6 and a conductive layer C6 in addition to the dielectric layer IN1, the conductive layer C1, the dielectric layer IN2, and the conductive layer C2. Further, the dielectric layer IN6, the conductive layer C6, the dielectric layer IN1, the conductive layer C1, the dielectric layer IN2, and the conductive layer C2 are, for example, sequentially formed on the first surface S1. Description of materials of the dielectric layer IN6 and the conductive layer C6 may refer to the description of the materials of the dielectric layer IN1 and the conductive layer C1, so description thereof is not repeated herein. In addition, the electronic device 1C may further include a solder resist layer 26 covering the first circuit structure 13C. The solder resist layer 26 exposes a plurality of contact pads CK2, so as to facilitate forming the plurality of second connectors 17 on the plurality of contact pads CK2. In the electronic device 1C, the electronic element 14 is, for example, an electrical integrated circuit (EIC), and the electronic device 1C may further include an electronic element 27 and an optical fiber 28. A plurality of pads 270 of the electronic element 27 may be connected to the plurality of contact pads CK2 through the plurality of second connectors 17. The electronic element 27 is, for example, a photonic integrated circuit (PIC), and the electronic element 27 is optically coupled to the optical fiber 28. For instance, the optical fiber 28 may be embedded in the packaging layer 19 and an end of the optical fiber 28 may be connected to the electronic element 27, but the disclosure is not limited thereto. Other optical coupling methods between the electronic element 27 and the optical fiber 28 are also included in the protection scope of the disclosure.

A second circuit structure 16C may further include a dielectric layer IN7 in addition to the dielectric layer IN3, the conductive layer C3, the dielectric layer IN4, and the conductive layer C4. Further, the dielectric layer IN3, the conductive layer C3, the dielectric layer IN4, the conductive layer C4, and the dielectric layer IN7 are, for example, sequentially formed on the second surface S2. Description of a material of the dielectric layer IN7 may refer to the description of the material of the dielectric layer IN3, so description thereof is not repeated herein. In addition, the electronic device 1C may further include a solder resist layer 29 covering the second circuit structure 16C. The solder resist layer 29 exposes a plurality of contact pads CK4, so as to facilitate forming the plurality of first connectors 15 on the plurality of contact pads CK4.

In view of the forgoing, in the embodiments of the disclosure, by providing the buffer layer and/or designing the W/D or the thickness T of the buffer layer, the structural strength of the substrate may be improved, and cracks generated in the substrate or interface delamination may be reduced.

The foregoing embodiments are merely described to illustrate the technical means of the disclosure and should not be construed as limitations of the disclosure. Even though the foregoing embodiments are referenced to provide detailed description of the disclosure, a person having ordinary skill in the art should understand that various modifications and variations can be made to the technical means in the disclosed embodiments, or equivalent replacements may be made for part or all of the technical features. Nevertheless, it is intended that the modifications, variations, and replacements shall not make the nature of the technical means to depart from the scope of the technical means of the embodiments of the disclosure.

Although the embodiments of the disclosure and advantages thereof are disclosed as above, it should be understood that a person having ordinary skill in the art may make changes, substitutions, and modifications without departing from the spirit and scope of the disclosure. Further, the features between the embodiments may be randomly mixed and replaced to form other new embodiments. Moreover, the scope of the disclosure is not intended to be limited to the particular embodiments of the processes, machines, manufactures, compositions of matters, means, methods, and steps described in the specification. As a person having ordinary skill in the art will readily appreciate from the disclosure, the processes, machines, manufacture, compositions of matters, means, methods, or steps, presently existing or later to be developed, that perform substantially the same function or achieve substantially the same result as the corresponding embodiments described herein may be utilized according to the disclosure. Accordingly, the claims of the disclosure are intended to include within their scope of such processes, machines, manufacture, compositions of matter, means, methods, and/or steps. Further, each claim constitutes an individual embodiment, and the scope of the disclosure further covers a combination of each claim and the respective embodiment. The protection scope of the disclosure shall be defined by the appended claims.

What is claimed is:

1. An electronic device, comprising:
a substrate having a first surface, a second surface opposite to the first surface, and a through hole, wherein an inner wall of the through hole is connected to the first surface and the second surface;
a buffer layer covering the first surface, the second surface, and the inner wall;
a conductor disposed in the through hole;
a first circuit structure disposed on the first surface;
an electronic element disposed on the first circuit structure; and
a plurality of first connectors disposed on the second surface and electrically connected to the electronic element through the conductor and the first circuit structure,
wherein the through hole has a width W and a depth D, W/D is greater than or equal to 0.01 and less than or equal to 0.5, and a thickness T of the buffer layer is greater than or equal to 0.01 μm and less than or equal to 10 μm.

2. The electronic device according to claim 1, wherein T/W is greater than or equal to 0.002 and less than or equal to 0.2.

3. The electronic device according to claim 1, further comprising:
a second circuit structure disposed on the second surface and located between the substrate and the plurality of first connectors.

4. The electronic device according to claim 3, wherein the electronic element is electrically connected to the second circuit structure through the conductor and the first circuit structure.

5. The electronic device according to claim 3, further comprising:
a plurality of second connectors, wherein the electronic element is electrically connected to the first circuit structure through the plurality of second connectors, and a pitch of two adjacent first connectors among the plurality of first connectors is greater than a pitch of two adjacent second connectors among the plurality of second connectors.

6. The electronic device according to claim 1, wherein a ratio of toughness of the buffer layer to toughness of a dielectric layer of the first circuit structure is greater than or equal to 0.1 and less than or equal to 10.

7. The electronic device according to claim 1, wherein toughness of the buffer layer is greater than or equal to 0.1 kJ/m2 and less than or equal to 100 KJ/m2.

8. The electronic device according to claim 1, wherein a thickness of a dielectric layer of the first circuit structure is greater than the thickness of the buffer layer.

9. The electronic device according to claim 8, wherein the thickness of the dielectric layer of the first circuit structure is greater than or equal to 5 μm and less than or equal to 25 μm.

10. The electronic device according to claim 1, wherein the conductor fills a space outside the buffer layer in the through hole.

11. The electronic device according to claim 1, wherein a thickness of the conductor on the first surface or the second surface is greater than a thickness of the buffer layer covering the first surface or the second surface, and the thickness of the buffer layer covering the first surface or the second surface is greater than a thickness of the buffer layer covering the inner wall.

12. The electronic device according to claim 11, further comprising:
a dielectric layer filling a space outside the buffer layer and the conductor in the through hole.

13. The electronic device according to claim 12, wherein a dissipation factor of the dielectric layer is less than 0.01.

14. The electronic device according to claim 1, further comprising:
an element integration layer disposed between the substrate and the first circuit structure and comprising another electronic element electrically connected to the electronic element through the first circuit structure.

15. The electronic device according to claim 1, wherein the substrate further comprises a blind hole, and the electronic device further comprises:
another electronic element disposed in the blind hole and electrically connected to the electronic element through the first circuit structure.

16. The electronic device according to claim 1, wherein a material of the substrate comprises glass or ceramic.

17. A manufacturing method of an electronic device, comprising:
forming a through hole in a substrate, wherein an inner wall of the through hole is connected to a first surface of the substrate and a second surface of the substrate, and the second surface is opposite to the first surface;
covering the first surface, the second surface, and the inner wall with a buffer layer;
providing a conductor in the through hole;
providing a first circuit structure on the first surface;
arranging an electronic element on the first circuit structure; and
providing a plurality of first connectors on the second surface, wherein the plurality of first connectors are electrically connected to the electronic element through the conductor and the first circuit structure, wherein the through hole has a width W and a depth D, W/D is greater than or equal to 0.01 and less than or equal to 0.5, and a thickness T of the buffer layer is greater than or equal to 0.01 μm and less than or equal to 10 μm.

18. The manufacturing method of the electronic device according to claim 17, wherein the method of forming the through hole comprises:
irradiating a portion of the substrate with a laser; and
removing the portion of the substrate irradiated by the laser with an etchant.

19. The manufacturing method of the electronic device according to claim 17, wherein the method of forming the buffer layer comprises forming a material of the buffer layer on the first surface, the second surface, and the inner wall by a chemical vapor deposition process.

20. The manufacturing method of the electronic device according to claim 17, wherein the method of forming the buffer layer comprises immersing the substrate having the through hole formed therein in a polymer solution.
